(19) United States
(12) Patent Application Publication
(10) Pub. No.: US 2014/0057139 A1
(43) Pub. Date: Feb. 27, 2014

(54) SELF-CONTAINED SOLAR-POWERED ENERGY SUPPLY AND STORAGE SYSTEM

(71) Applicant: ANTECY B.V., HOEVELAKEN (NL)

(72) Inventors: Paul O'CONNOR, HOEVELAKEN (NL); Gerrit VAN PUTTEN, HOEVELAKEN (NL); Jacobus Cornelis RASSER, AMSTERDAM (NL); Sasa MARINIC, ZEEWOLDE (NL)

(73) Assignee: ANTECY B.V., HOEVELAKEN (NL)

(21) Appl. No.: 14/051,553

(22) Filed: Oct. 11, 2013

Related U.S. Application Data
(63) Continuation of application No. PCT/EP2012/056582, filed on Apr. 11, 2012.
(60) Provisional application No. 61/473,829, filed on Apr. 11, 2011.

(51) Int. Cl. H01M 8/06; H01M 8/18; H01L 31/058; H01M 8/10

(52) U.S. Cl. CPC H01M 8/06; H01M 8/1011; H01M 8/184; H01L 31/0586
USPC 429/9; 60/772

(57) ABSTRACT

A system is disclosed for energy supply and storage. The system is self-contained. It comprises a means for generating solar electric power. Electric power can be converted to a liquid fuel, such as methanol, in a reversible liquid fuel cell. The liquid fuel is stored. When demand for electric power exceeds the supply of solar power, electric power is generated in the liquid fuel cell using stored liquid fuel.

### CROSS-REFERENCE TO RELATED APPLICATIONS

This application is a continuation application of PCT application number PCT/EP2012/056582 filed on 11 Apr. 2012, which claims priority from U.S. provisional application No. 61/473,829 filed on 11 Apr. 2011. All applications are hereby incorporated by reference in their entireties.

### BACKGROUND OF THE INVENTION

1. Field of the Invention

The invention relates generally to a self-contained solar-powered energy supply and storage system, and more particularly to such a system using methanol for energy storage.

2. Description of the Related Art

To address the need for energy from renewable resources and for reducing the reliance on fossil fuels, an increasing use is being made of solar energy for generating electricity. Solar energy can be converted to electrical energy using photovoltaic cells or thermal solar cells.

In photovoltaic cells sunlight is used to generate electricity in an array of semiconductor wafers, typically silicon wafers. Although some electricity can be generated during periods of overcast weather, full, bright sunlight is required for optimum photovoltaic cell efficiency.

Thermal solar cells generate electricity in an indirect manner. Water is pumped through a network of tubes that are placed in shallow trays, which are tilted towards the sun. Solar heat converts water in the tubes to steam, which is used to propel a conventional turbine. Other forms of thermal solar cells include the solar updraft tower and the molten salt installation. The updraft tower combines the chimney effect, the greenhouse effect and the wind turbine. Air is heated by sunshine and contained in a very large greenhouse-like structure around the base of a tall chimney, and the resulting convection causes air to rise up the updraft tower. This airflow drives turbines, which produce electricity.

The molten salt tower concentrates intensely hot sunlight onto what is called a collector, which then eventually transfers heat to molten salt where it is stored for later use. Heat energy stored in the molten salt is used to help boil water when the weather is cloudy, and exclusively at night due to the absence of sunlight. Simply put: this is the storage of heat to boil water later if there is not enough solar energy to boil the water vigorously enough at that time.

Thermal solar cells offer a limited opportunity for storing solar energy in the form of steam. However, energy storage in the form of steam is capital intensive, as it requires high pressure vessels and extensive insulation. Thermal solar cells do not lend themselves well for decentralized power generation, because of the capital requirements.

Buildings, such as office buildings and homes, equipped with photovoltaic cells generally are connected to the grid. Excess electric energy, generated on bright sunny days when the building's electricity requirements are low, is sold to the grid. The building's owner receives a credit to be applied to electricity purchases from the grid when the building's electricity requirements exceed the power generated by its photovoltaic cells. However, the building's ability to sell electricity is when supply is plentiful and demand is low, whereas its need to purchase electricity is when supply is limited and demand is high. For this reason it must pay a much higher price for the electricity it purchases than it receives for the electricity is sells.

It is possible to convert electric power to hydrogen, for example using electrolysis, and to convert hydrogen back to electric power using a fuel cell. In principle it would be possible to create a self-contained solar-powered energy supply and storage system using excess solar power to generate hydrogen; storing hydrogen; and using hydrogen to generate electricity when demand exceeds the power generated by the solar cells. However, storage and handling of hydrogen requires sophisticated equipment and high capital investment. A hydrogen based system does not lend itself well for decentralized power generation.

Thus, there is a need for a self-contained solar-powered energy supply and storage system using a liquid fuel, such as methanol or dimethylether (DME), as energy storage medium.

### BRIEF SUMMARY OF THE INVENTION

The present invention addresses these problems by providing a self-contained, solar-powered energy supply and storage system comprising:

an array of solar cells for converting solar energy to electric energy;
at least one reversible direct liquid fuel cell (DLFC) for converting electric energy to liquid fuel and for converting liquid fuel to electric energy;
a liquid fuel storage tank.
Preferred liquid fuels include methanol and dimethylether (DME).

Another aspect of the invention comprises a process for supplying on-demand electric power to a power consumption system, said process comprising the steps of:

converting solar power to electric power using an array of solar cells;
if the production of electric power exceeds a demand for electric power by the power consumption system, converting excess electric power to liquid fuel using a reversible DLFC;
storing produced liquid fuel in a liquid fuel storage tank;
if the demand for electric power by the power consumption system exceeds the production of electric power by the array of photovoltaic cells, converting liquid fuel from the storage tank to electric power, using the reversible DLFC.

### BRIEF DESCRIPTION OF THE DRAWINGS

The features and advantages of the invention will be appreciated upon reference to the following drawings, in which:

FIG. 1 is a diagrammatic representation of an embodiment of the self-contained, solar-powered energy supply and storage system of the present invention.

FIG. 2 is a diagrammatic representation of an alternate embodiment of the self-contained, solar-powered energy supply and storage system of the present invention.

FIG. 3 is a diagrammatic representation of a reversible direct liquid fuel cell in normal operation.

FIG. 4 is a diagrammatic representation of a reversible direct liquid fuel cell in reverse operation.

FIG. 5 shows the system of FIG. 1 with peripheral supply lines.

### DETAILED DESCRIPTION OF THE INVENTION

The self-contained, solar-powered energy supply and storage system of the present invention (hereinafter referred to as the energy system) relies on the generation of electricity using solar cells. The term “solar cells” as used herein refers to any type of cell capable of using solar radiation to generate electric power. The term “solar radiation” refers to electromagnetic radiation from the sun received at the earth's surface, and includes infrared, visible light, and u.v. The term “solar cell” includes photovoltaic cells and thermal solar cells.

The invention will be described in more detail with reference to photovoltaic cells as the means for converting solar power to electric power. It will be understood that other types of solar cells, such as thermal solar cells, can be used in addition to or in lieu of photovoltaic cells.

An array of solar cells is used to supply a building or group of buildings with electric power. The amount of electric power generated by the solar cells depends on the solar elevation; the angle of the sun relative to the solar cells; the atmospheric conditions, in particular the presence or absence of cloud cover; contamination of the atmosphere with dust particles, and the like.

The demand of electric power by the building varies with the seasons and with the time of day. If the building is an office building, for example, the demand for electric power may be high during the work day, but low at night and during weekends. By contrast, the demand for electric power by residential buildings tends to be high during weekends and during evening hours.

For the system of the invention it is advantageous to dimension the array of photovoltaic cells to supply, on an annual basis, the building's forecast annual demand of electric power. A slight over-dimensioning of the photovoltaic array, for example by 10% or 20%, may be desirable to allow the system to cope with years of lower than average sunshine hours.

It will be understood that only very rarely will the supply of electric power by the array of photovoltaic cells be perfectly matched by the contemporaneous demand. In most instances there is either an excess supply, or an excess demand. The system can be provided with a bank of batteries to deal with short-term imbalances in supply and demand. However, for longer term imbalances the system relies on storing energy in the form of a liquid fuel, such as methanol or DME, or a mixture of methanol and DME. DME is a gas at room temperature, which readily liquefies at under moderate pressure. DME is particularly attractive for use in a diesel fuel, because of its high cetane number.

The system will be described in more detail with reference to methanol as the liquid fuel.

The system comprises a methanol fuel cell and a methanol storage tank. The methanol fuel cell can be a hydrogen fuel cell, combined with a methanol reformer. The methanol reformer converts methanol to hydrogen, which is used as the actual fuel for the fuel cell.

In an alternate embodiment the fuel cell is a direct methanol fuel cell, which directly converts methanol to electric power without requiring methanol to first be converted to hydrogen.

The capacity of the fuel cell is such that it can deal with peak demands for electric power, even in the absence of any solar electric power. It is advantageous to provide a battery of solar cells with a combined capacity sufficient to deal with a forecast peak demand of electric power. The system can be provided with a controller that switches on a number of fuel cells sufficient to meet the immediate demand of electric power to the extent this demand exceeds the supply of solar electric power.

When a direct methanol fuel cell generates electricity from methanol, carbon dioxide is formed at the anode:

CH₃OH+H₂O→6H⁺+6e⁻+CO₂ (1)

And water is formed at the cathode:

$$\frac{3}{2} {O}_{2} + 6 {H}^{+} + 6 {e}^{-} \to 3 {H}_{2} O \qquad ( 2 )$$

The overall reaction being:

$${CH}_{3} OH + \frac{3}{2} {O}_{2} \to 2 {H}_{2} O + {CO}_{2} \qquad ( 3 )$$

It is advantageous to store carbon dioxide generated at the anode, for later use. Carbon dioxide can be stored in an appropriate storage tank, under pressure. It may be desirable to remove water vapor, which is easily accomplished by selective condensation.

In the alternative carbon dioxide can be reversibly absorbed in a carbon dioxide absorbent, such as alumina/magnesia, hydrotalcite, and the like. Water can be stored in a water storage tank.

Methanol used as a fuel cell fuel to complement the production of solar electricity is formed during periods that the supply of solar electricity exceeds the demand for electric power.

A direct methanol fuel cell can be operated in reverse by supplying electric power to the cell and converting electric power to chemical energy. However, when a DMFC is operated in reverse it acts as a water electrolysis cell, generating hydrogen and oxygen, not methanol.

Thus, additional measures are necessary to produce methanol during the reverse operation of the fuel cell. These measures include:

Supplying carbon dioxide to the anode (where hydrogen is formed); and
Reacting carbon dioxide with hydrogen to form methanol:

3H₂+CO₂→CH₃OH+H₂O (4)

Carbon dioxide used in this reaction preferably is carbon dioxide that was collected and stored during the electricity generating cycle of the fuel cell.

Reaction (4) is preferably carried out in the presence of a catalyst. Examples of suitable catalysts include materials comprising Ni; Fe; Cu; Mn; Pt; Ru; Ir; Re; Zn; Au; and combinations thereof, in particular Pt/Ru; Pt/Ir, Pt/Re en Pt/Ir/Re, Cu/Zn; Cu/Zn/Al; Mn/Cu/Zn; Cu/Zn/Al/Mn; combinations of Au with Cu, Zn, Mn, Al, Fe, and/or Ni.

The catalytic metals can be deposited on a support material, such as carbon, for example by impregnation with a soluble salt form of the metal. The metal salt is subsequently converted to its oxide by calcination in air. The catalyst is reduced in hydrogen or a hydrogen-containing reducing gas, or a reducing agent such as NaBH₄. For example, a 5% solution of NaBH₄ provides good reduction at 80° C. It will be understood that noble metals tend to be present in metallic form, whereas metals such as Zn or Al tend to be present as an oxide. Other metals, such as Cu, may be only partially reduced. An example of this reaction is reported in Michael Specht and Andreas Bandi “The Methanol-Cycle”—Sustainable Supply of Liquid Fuels”, Center of Solar Energy and Hydrogen Research (ZSW), Hessbruehlstr. 21C, 70565 Stuttgart.

Reaction (4) may take place at or near the anode of the DMFC. In an alternate embodiment hydrogen is collected at the anode as it is formed, and transported to a nearby methanol reactor. In the methanol reactor hydrogen is reacted with carbon dioxide in the presence of a suitable catalyst.

Non-metallic catalysts have been reported as being able to catalyze the reaction of carbon dioxide and hydrogen to form methanol at relatively low pressures (less than 10 bar, preferably less than 5 bar) and modest reaction temperatures (<250° C.). Such reaction conditions are particularly desirable for use of the system near or in urban locations, for example in office buildings, residential dwellings, village communities, and the like, where safety is paramount.

One group of catalysts that can be used for low pressure/low temperature methanol synthesis includes the frustrated Lewis pairs (FLPs). An example of a suitable FLP is the acid/base pair consisting of the base tetramethylpiperidine (TMP) and the acid B(C₆F₅)₃, which has been reported to catalyze the reaction at 160° C. and less than 3 bar (see http://newenergyandfuel.com/http:/newenergyandfuel/com/2010/01/19/a-new-way-to-make-methanol-fuel/)

Another group of suitable catalysts includes the stable carbenes, in particular N-heterocyclic carbenes (see http://www.alternative-energy-news.info/new-way-to-convert-co2-into-methanol/)

For decentralized power generation it may be desirable to use a miniaturized reactor, such as a micro-channel reactor.

It will be understood that the system can be designed to produce liquid fuel, such as methanol, in excess, i.e., the amount of liquid fuel produced is more than is required for a long term self-sufficient operation of the system. This approach is particularly attractive in geographic areas that receive abundant amounts of solar energy. Excess liquid fuel can be used for powering vehicles, either “as-is” or blended with other liquid fuels, such as gasoline or diesel fuel.

The present invention also provides a process for supplying on-demand electric power to a power consumption system.

In the process, solar power is converted to electric power using an array of solar cells.

If the production of electric power exceeds a demand for electric power by the power consumption system, converting excess electric power to methanol using a reversible DMFC. The methanol is stored in a methanol storage tank.

The system can be modified by using a different liquid fuel to replace methanol. An example of a suitable liquid fuel is dimethylether. DME can be synthesized in the process described above for the synthesis of methanol, using a DME synthesis catalyst. Examples of suitable DME synthesis catalysts include CuO, ZnO, Al₂O₃, Ga₂O₃, MgO, ZrO₂, and mixtures thereof. Suitable supports for these catalysts include alumina, and Al/Mg mixed oxides, such as hydrotalcite.

Dependent on the selectivity of the catalyst, the synthesis may produce mixtures of methanol and DME, and potentially lesser amounts of other liquid fuels, such as ethanol, methylethyl ether, and diethyl ether. Such mixtures can be stored and used as liquid fuel for the fuel cell, without requiring a separation or purification step.

Returning now to the specific example of methanol as the liquid fuel, if the demand for electric power by the power consumption system exceeds the production of electric power by the array of photovoltaic cells, converting methanol form the storage tank to electric power, using the reversible DMFC.

The power consumption system can be a building or a group of buildings, for example one or more office buildings, one or more residential buildings, or one or more single family homes. It can be advantageous to apply the process to a combination of one or more office buildings and one or more residential buildings, as the peak demand hours of office buildings and residential buildings tend to be off-set against each other, with office buildings having their demand peaks during the work day, and residential buildings during evening hours and weekends.

The skilled person will appreciate that electric power generated by solar cells and fuel cells is low voltage, direct current (DC). This type of electric power is suitable for powering many appliances, such as telephones, LED light sources, TV sets, amplifiers, radios, and small kitchen appliances. Other appliances, such as washers, dryers and refrigerators, are built for operation on standard power (e.g., 110 V, 60 Hz AC in North America and Japan; 240 V, 50 Hz AC in Europe). The conversion of low voltage, direct current power to standard power is highly inefficient, causing losses of up to 30%. Conversion back to low voltage, direct current power is also wasteful. It is desirable to convert as little as possible. However, low voltage power incurs significant transportation losses, and requires large diameter cables.

The power consumption system can be optimized by placing appliances operated on low voltage DC as close as possible to the power supply (solar cells and DMFC), so that these appliances can be powered directly by the DC power source. Appliances requiring standard power can be placed at a greater distance. Power conversion from low voltage DC to standard voltage AC takes place in a location near the power source. The AC power can be transported over a greater distance without appreciable losses and without requiring unduly heavy cabling.

As a practical example, a single family two-story home can be equipped with solar cells on the roof, and a reversible DMFC on the roof or in the attic. Rooms that have low voltage appliances (computers, TV sets, lighting) can be located on the top floor, so that the low voltage appliances are a short distance from the power source. Larger appliances, such as refrigerators, washer, dryer, VAC, can be placed on the ground floor or in the basement. A converter is placed near the power supply to provide standard voltage AC to the large appliances on the ground floor and in the basement.

### DESCRIPTION OF SPECIFIC EMBODIMENTS

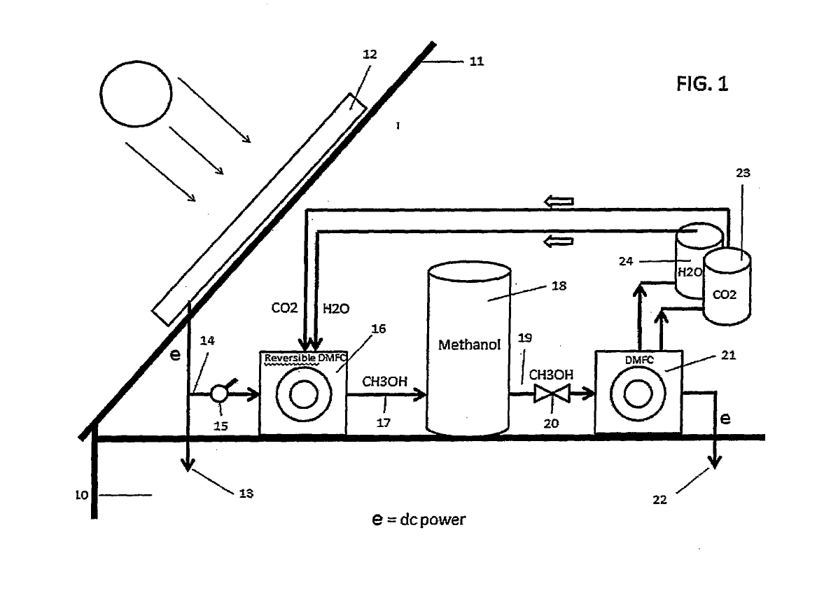

The following is a description of certain embodiments of the invention, given by way of example only and with reference to the drawings. Referring to FIG. 1, an embodiment is shown of the system of the present invention.

Building 10 has a roof 11, on which is mounted an array of solar panels 12. Electricity generated by solar panels 12 is provided to electric appliances in building 10 at supply line 13. The electric appliances may include lighting, heating, cooling, washing, drying, and similar appliances (not shown). The electrical system of building 10 may include a bank of batteries for storing electrical energy, and a converter for converting low voltage DC power to standard AC power, for the operation of standard appliances.

Via line 14, electric power from solar array 12 can be diverted to a reversible DMFC 16. Line 14 is provided with switch 15, so that electric power may be diverted to DMFC 16 only if excess power is available, for example only when the power supply provided by solar panels 12 exceed the demand of electric power by building 10, and the bank of batteries is fully charged. Switch 15 may be operated by a microcontroller (not shown).

Methanol produced by reversible DMFC 16 is transferred to methanol storage tank 18 via conduit 17, where it is stored for future use in DMFC 21.

When demand for electric power by building 10 exceeds the supply from solar panel array 12, switch 15 is closed so that no electric power is diverted to reversible DMFC 16. The supply imbalance may be compensated by drawing power from the bank of batteries. If the supply shortage is analyzed to be of a persistent nature (for example, because the microcontroller recognizes the time to be between sunset and sunrise), valve 20 is opened to supply methanol to DMFC 21, and operation of DMFC 21 is started.

During operation of DMFC 21, electric power is provided to building 10 via line 22. Carbon dioxide and water, generated during operation of DMFC 21, are separated from each other, for example by selective condensation. Carbon dioxide is stored in carbon dioxide storage tank 23. Water is stored in water storage tank 24. Both are available for use in reversible DMFC 16.

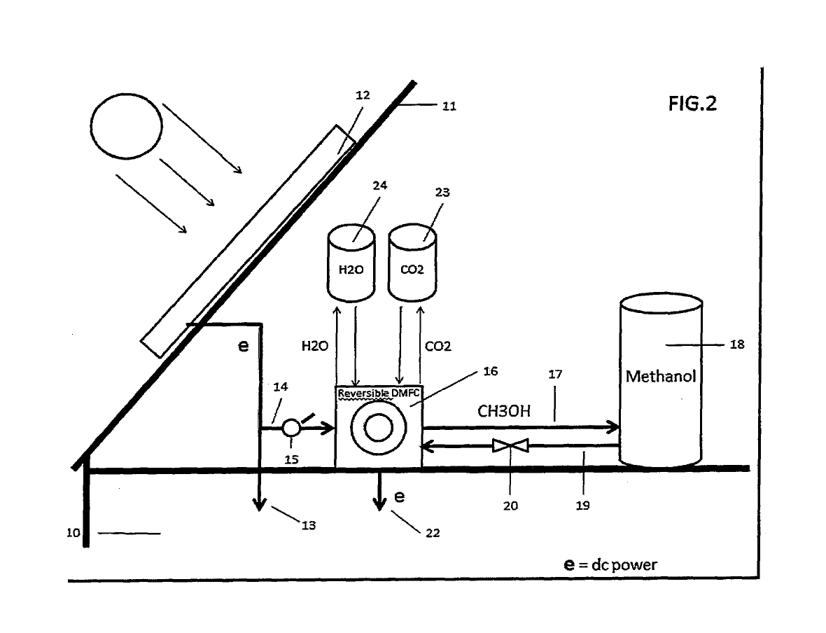

FIG. 2 shows an alternate embodiment of the system of the invention. As in the system of FIG. 1, electric power from solar panel 12 is fed into building 10 via line 13. Excess power can be diverted to reversible DMFC 16 via line 14, with switch 15 in closed position. When operating in reverse mode, reversible DMFC 16 receives water from water storage tank 24, and carbon dioxide from carbon dioxide storage tank 23. During reverse operation reversible DMFC produces methanol, which is conveyed to methanol storage tank 18 via conduit 17.

When the demand for electric power by building 10 exceeds the supply from solar panel 12, reversible DMFC can be put in normal operation. During normal operation methanol from methanol storage tank 18 can be supplied to reversible DMFC 16 via conduit 19, by opening valve 20. During normal operation, reversible DMFC produces electric power, which is fed into building 10 via line 22. Carbon dioxide produced by DMFC 16 during normal operation is stored in carbon dioxide storage tank 23; water produced by DMFC 16 during normal operation is stored in storage tank 24.

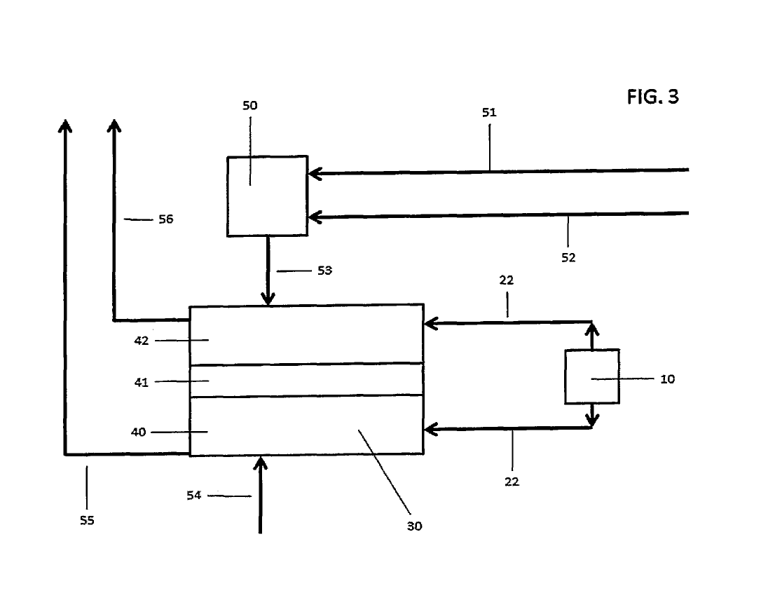

FIG. 3 shows a DMFC in normal operation. Fuel cell 30 comprises a cathode 40, an anode 42, and an electrolyte 41. Typically, the cathode and the anode comprise a noble metal, such as Pt or Pt/Ru. Water is supplied to mixing tank 50 via conduit 51. Methanol is supplied to mixing tank 50 via conduit 52. A methanol/water mixture is supplied from mixing tank 50 to anode 42 via conduit 53. Oxygen, or an oxygen-containing gas, such as air, is supplied to cathode 40 via line 54.

Water is collected at cathode 40, and conveyed via conduit 55 to a water storage tank (not shown), for future use. Carbon dioxide is collected at anode 42, and conveyed via conduit 56 to a carbon dioxide storage tank (not shown), for future use.

Electric power is fed into building 10 via line 22.

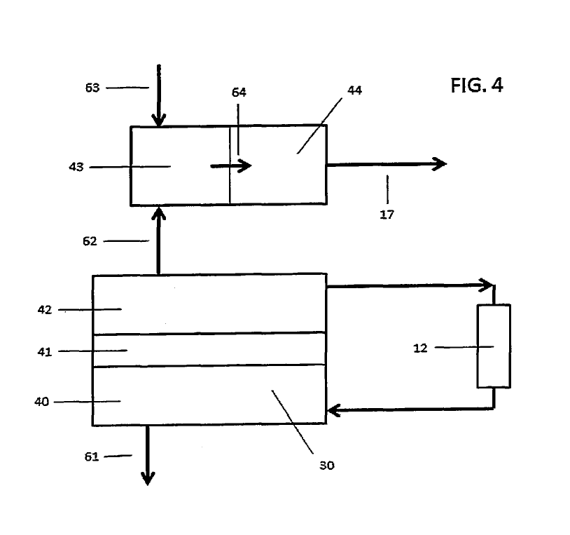

FIG. 4 shows the reversible DMFC in reverse operation. Power from solar panel 12 is fed into fuel cell 30. Oxygen produced at cathode 40 is conveyed via conduit 61 to an oxygen storage tank (not shown), for future use.

Hydrogen produced at anode 42 is conveyed to reverse water gas shift (WGS) reactor 43, and mixed with carbon dioxide from a carbon dioxide storage tank (not shown), which enters reverse WGS reactor 43 via conduit 63. In reverse WGS reactor 43, hydrogen is reacted with carbon dioxide to form a syngas mixture. The syngas mixture produced in reactor 43 is conveyed to methanol reactor 44 via conduit 64. Methanol reactor 44 contains a methanol synthesis catalyst, such as CuO/ZnO.

Methanol produced in methanol reactor 44 is conveyed via conduit 17 to a methanol storage tank (not shown), for future use.

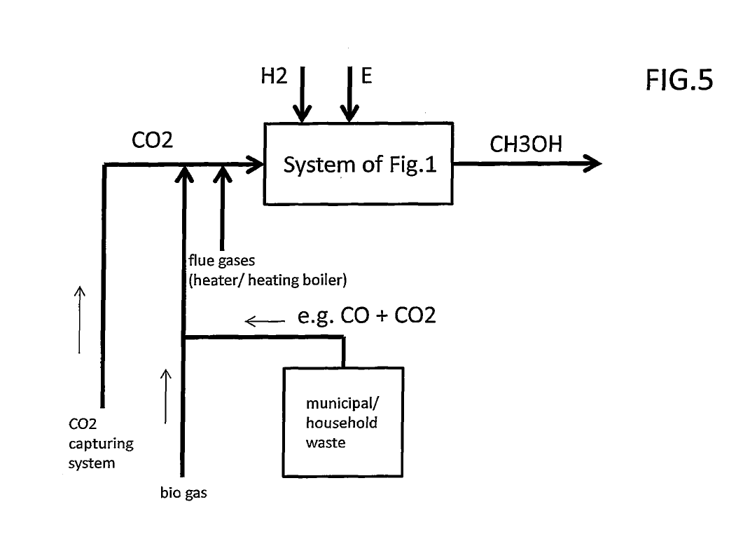

FIG. 5 shows the system of FIG. 1, further showing alternate and additional sources of carbon dioxide. Additional carbon dioxide can be used to produce additional methanol. Potential additional sources of carbon dioxide can include flue gases of a heater and/or heater/boiler; biogas produced by fermentation or composting of waste from household, municipal or agricultural sources; or a carbon dioxide capturing system that releasably captures carbon dioxide from a flue gas or from ambient air. In the case of flue gas, the carbon dioxide source may further contain carbon monoxide, which favors methanol production.

Many modifications in addition to those described above may be made to the structures and techniques described herein without departing from the spirit and scope of the invention. Accordingly, although specific embodiments have been described, these are examples only and are not limiting upon the scope of the invention.

What is claimed is:

1. A self-contained, solar-powered energy supply and storage system comprising:
a. an array of solar cells for converting solar energy to electric energy;
b. at least one direct liquid fuel cell (DLFC) for converting electric energy to liquid fuel;
c. a means for converting the liquid fuel to electric energy;
d. a liquid fuel storage tank; and
e. a carbon dioxide capturing system that releasably captures carbon dioxide from flue gas or ambient air.

2. The system of claim 1 wherein the means for converting the liquid fuel to electric energy comprises (i) the direct liquid fuel cell for converting electric energy to liquid fuel in reverse operation; a combination of a reformer for reforming the liquid fuel to hydrogen and a hydrogen fuel cell; (iii) a high-efficiency turbine generator; (iv) any combination of (i), (ii), and (iii).

3. The system of claim 1 further comprising a means for converting carbon dioxide.

4. The system of claim 3 wherein the means for converting carbon dioxide is the direct liquid fuel cell.

5. The system of claim 3 wherein the means for converting carbon dioxide is a catalytic thermo-conversion reactor.

6. The system of claim 3 wherein carbon dioxide is produced from a renewable source.

7. The system of claim 6, wherein carbon dioxide is produced from a conversion of biomass or capture from air.

8. The system of claim 3 wherein carbon dioxide is captured from flue gas or from biogass produced from agricultural, municipal or domestic waste.

9. The system of claim 1 wherein the liquid fuel is methanol, DME, or a mixture thereof.

10. The system of claim 9, wherein the liquid fuel is methanol, and the DLFC is a DMFC.

11. The energy supply and storage system of claim 10 wherein the reversible DMFC has an electricity production mode and a methanol production mode.

12. The energy supply and storage system of claim 11 wherein the reversible DMFC produces water vapor and carbon dioxide in the electricity production mode, and wherein the produced carbon dioxide is sequestered from water vapor, and stored.

13. The energy supply and storage system of claim 12 wherein, in the methanol production mode, carbon dioxide is supplied to the anode to form methanol.

14. The energy supply and storage system of claim 13 wherein the anode is a catalyst for reacting hydrogen and carbon dioxide to form methanol.

15. The energy supply and storage system of claim 10 wherein, in the methanol production mode, the reversible DMFC produces hydrogen at the anode, said hydrogen being led to a reactor for reaction with carbon dioxide in the presence of a catalyst, to form methanol.

16. The energy supply and storage system of claim 15 wherein the catalyst in the reactor is a hydrogenation catalyst, selected from the group consisting of the metals Ni, Fe, Cu, Mn, Pt, Pt/Ru, Pt/Ir, Pt/Re en Pt/Ir/Re, Cu/Zn, Cu/Zn/AI, Mn/Cu/Zn, Cu/Zn/Al/Mn; Au; mixtures of Au and one or more of Cu, Zn, Mn, Al, Fe, Ni; oxides of any of these metals; carbon doped or coated with any of these metals or their oxides.

17. The energy supply and storage system of claim 15 wherein the catalyst comprises a frustrated Lewis pair.

18. The energy supply and storage system of claim 15 wherein the catalyst comprises a stable carbene.

19. The energy supply and storage system of claim 18, wherein the catalyst comprises N-heterocyclic carbene.

20. A process for supplying on-demand electric power to a power consumption system, said process comprising the steps of:
a. converting solar power to electric power using an array of solar cells;
b. if the production of electric power exceeds a demand for electric power by the power consumption system, converting excess electric power to a liquid fuel using a reversible DLFC;
c. storing produced liquid fuel in a liquid fuel storage tank;
d. if the demand for electric power by the power consumption system exceeds the production of electric power by the array of photovoltaic cells, converting liquid fuel from the storage tank to electric power, using the reversible DLFC.

21. The process of claim 20 wherein the liquid fuel is methanol, DME, or a mixture thereof.

22. The process of claim 20 wherein the power consumption system comprises a building.

23. The process of claim 22 wherein the building is a residential building.

24. The process of claim 23 wherein the building is a single family home.

25. The process of claim 22 wherein the building contains electrical appliances of a first kind, designed to operate at low voltage DC electric power, and electrical appliances of a second kind designed to operate at household voltage AC electric power; wherein the electrical appliances of the first kind are predominantly positions in close proximity to the reversible DLFC.

26. The process of claim 25 wherein the electrical appliances of the second kind receive power from the array of photovoltaic cells and/or the reversible DLFC via a DC/AC convertor, and wherein said DC/AC convertor is placed in close proximity of the reversible DLFC.

27. The process of claim 25 wherein the average distance of the appliances of the first kind to the reversible DLFC is less than the average distance of the appliances of the second kind to the reversible DLFC.
